(19) United States
(12) Patent Application Publication
(10) Pub. No.: US 2026/0150410 A1
(43) Pub. Date: May 28, 2026

(54) POWER SEMICONDUCTOR DEVICE

(71) Applicant: DB HiTek Co., Ltd., Bucheon-si (KR)

(72) Inventors: Hong Sik SHIN, Bucheon-si (KR); Jin Tae YU, Bucheon-si (KR); Jae Hoon KIM, Bucheon-si (KR)

(21) Appl. No.: 19/020,262

(22) Filed: Jan. 14, 2025

(30) Foreign Application Priority Data
Nov. 25, 2024 (KR) 10-2024-0169308

(51) Int. Cl. H10D 89/60; H10D 62/10

(52) U.S. Cl. CPC H10D 89/713; H10D 62/106

(57) ABSTRACT

A power semiconductor device and, more particularly, a power semiconductor device allows electrostatic discharge (ESD) current to be discharged to a ground terminal when the current flows in by forming a guard ring region connected to the ground terminal between a resistance unit and a switching unit of the power semiconductor device.

### CROSS REFERENCE TO RELATED APPLICATION

The present application claims priority to Korean Patent Application No. 10-2024-0169308, filed Nov. 25, 2024, in the Korean Intellectual Property Office, the entire contents of which is incorporated herein for all purposes by this reference.

### BACKGROUND OF THE INVENTION

### Field of the Invention

The present disclosure relates to a power semiconductor device and, more particularly, to a power semiconductor device that allows electrostatic discharge (ESD) current to be discharged to a V_{SS} terminal when the current flows in by forming a guard ring region connected to the ground terminal between a resistance unit and a switching unit.

### Description of the Related Art

In general, a power semiconductor device may include a high voltage unit and a low voltage unit, and a bootstrap circuit may be used to ensure stable operation of the high voltage unit. The bootstrap circuit may include a capacitor connected to the high voltage unit to provide power. The bootstrap circuit may also include a diode that connects a capacitor to a driving power supply to charge the capacitor while the low voltage unit outputs low voltage, and prevents the driving power supply from being electrically connected to the high voltage unit while the high voltage unit outputs high voltage.

However, if high voltage is applied directly to the diode, the diode may be damaged. Accordingly, a separate transistor may be provided between the high voltage unit and the diode to prevent high voltage from being applied to the diode. When such a separate transistor is used, the size of the power semiconductor device may increase, and the distance traveled by electrons is increased due to the separate transistor while charging the capacitor, which may decrease an electric current heading to the capacitor.

In addition, in the case of ultra-high voltage (UHV) devices, the overall size is manufactured relatively large in order to obtain stable breakdown voltage characteristics, and when using a separate ESD protection device to protect the UHV device from electrostatic discharge, a device of similar size to the UHV device is used. The problem is that when using a separate ESD protection device like this, the area of the overall product increases significantly. To resolve this problem, UHV devices capable of self-protection against electrostatic discharge are being actively developed.

### DOCUMENTS OF RELATED ART

(Patent Document 0001) Korean Patent Application Publication No. 10-2012-0052478 “BOOTSTRAP CIRCUIT”

### SUMMARY OF THE INVENTION

The present disclosure has been made to solve the problems of the related art, and an objective of the present disclosure is to provide a power semiconductor device that allows electrostatic discharge (ESD) current to be discharged to a ground terminal when the current flows in by forming a guard ring region connected to the ground terminal between a resistance unit and a switching unit.

In addition, an objective of the present disclosure is to provide a power semiconductor device that further improves ESD protection performance by enabling silicon controlled rectifier (SCR) operation by forming a sixth contact region, a second well region and a third well region.

In addition, an objective of the present disclosure is to provide a power semiconductor device that reduces the overall size of the device by not utilizing a separate transistor to prevent high voltage from being applied to a switching unit from a high voltage unit.

In addition, an objective of the present disclosure is to provide a power semiconductor device that prevents a decrease in total current amount due to an increase in the length of a current movement path by ensuring that a P-TOP region formed in a resistance unit is spaced apart from a field oxide film thereabove.

The present disclosure may be implemented by embodiments having the following configuration to achieve the above-described objectives.

According to an embodiment of the present disclosure, there is provided a power semiconductor device, including: a high voltage unit configured to output high voltage; a low voltage unit configured to output low voltage; a capacitor configured to be electrically connected to the high voltage unit and to provide power to the high voltage unit while the high voltage is output; a switching unit configured to be electrically connected to the high voltage unit and the capacitor, to connect the capacitor to a driving power supply to charge the capacitor while the low voltage is output, and to prevent the high voltage unit and the driving power supply from being electrically connected to each other while the high voltage is output; a resistance unit configured to be electrically connected between the switching unit and the high voltage unit and to drop the high voltage to a voltage lower than a breakdown voltage of the switching unit while the high voltage is output; and a guard ring region between the switching unit and the resistance unit.

According to another embodiment of the present disclosure, in the power semiconductor device, the guard ring region may include: a first contact region of a second conductivity type on a surface side of a substrate; and a first well region of a second conductivity type surrounding the first contact region.

According to still another embodiment of the present disclosure, in the power semiconductor device, the first contact region is electrically connected to a ground terminal.

According to still another embodiment of the present disclosure, in the power semiconductor device, the guard ring region may further include a buried layer of a second conductivity type below the first well region.

According to still another embodiment of the present disclosure, the power semiconductor device may further include a first device isolation region between the switching unit and the resistance unit, wherein the first device isolation region may include: a first buried layer of a first conductivity type within the substrate; a second contact region of a first conductivity type on the surface side of the substrate; and a first impurity diffusion region of a first conductivity type between the first buried layer and the second contact region.

According to still another embodiment of the present disclosure, the power semiconductor device may further include a second device isolation region between the first device isolation region and the switching unit, wherein the second device isolation region may include: a second buried layer of a first conductivity type within the substrate; a third contact region of a first conductivity type on the surface side of the substrate; and a second impurity diffusion region of a first conductivity type between the second buried layer and the third contact region.

According to still another embodiment of the present disclosure, in the power semiconductor device, the guard ring region may be located between the first device isolation region and the second device isolation region.

According to still another embodiment of the present disclosure, in the power semiconductor device, the resistance unit may include: a deep well region of a second conductivity type extending from a substrate surface to a predetermined depth; a fourth contact region of a second conductivity type on a side of the substrate surface adjacent to the switching unit; and a fifth contact region of a second conductivity type on a side of the substrate surface adjacent to the high voltage unit, wherein the fourth contact region and the fifth contact region are surrounded by the deep well region.

According to still another embodiment of the present disclosure, in the power semiconductor device, the fourth contact region may be electrically connected to the switching unit, and the fifth contact region may be electrically connected to the high voltage unit.

According to still another embodiment of the present disclosure, in the power semiconductor device, the resistance unit may further include a second well region of a second conductivity type below the sixth contact region.

According to still another embodiment of the present disclosure, in the power semiconductor device, the resistance unit may further include a third well region of a first conductivity type within the sixth contact region and the second well region.

According to still another embodiment of the present disclosure, a power semiconductor device according to the present disclosure may include: a high voltage unit configured to output high voltage; a low voltage unit configured to output low voltage; a capacitor configured to be electrically connected to the high voltage unit and to provide power to the high voltage unit while the high voltage is output; a bipolar junction transistor configured to be electrically connected to the high voltage unit and the capacitor, to connect the capacitor to a driving power supply to charge the capacitor while the low voltage is output, and to prevent the high voltage unit and the driving power supply from being electrically connected to each other while the high voltage is output; a resistance unit configured to be electrically connected between the bipolar junction transistor and the high voltage unit and to drop the high voltage to a voltage lower than a breakdown voltage of the bipolar junction transistor while the high voltage is output; and a guard ring region between the bipolar junction transistor and the resistance unit, wherein the guard ring region may include: a first contact region of a second conductivity type located on a surface side of a substrate and electrically connected to a ground terminal; and a first well region of a second conductivity type surrounding the first contact region.

According to still another embodiment of the present disclosure, in the power semiconductor device, the bipolar junction transistor may include: an emitter region of a second conductivity type provided on the substrate; a base region of a first conductivity type provided on the substrate; and a collector region of a second conductivity type provided on the substrate, wherein the base region and the collector region may be electrically connected to the driving power supply, and the emitter region may be electrically connected to the resistance unit.

According to still another embodiment of the present disclosure, in the power semiconductor device, the resistance unit may include: a deep well region of a second conductivity type within the substrate; a field oxide film on the surface side of the substrate; and a P-TOP region spaced apart from the field oxide film within the deep well region.

According to still another embodiment of the present disclosure, in the power semiconductor device, the resistance unit may further include a single electrode layer on the field oxide film.

According to still another embodiment of the present disclosure, the power semiconductor device may further include: a first device isolation region between the bipolar junction transistor and the resistance unit; and a second device isolation region between the first device isolation region and the bipolar junction transistor, wherein the first device isolation region may include: a first buried layer of a first conductivity type within the substrate; a second contact region of a first conductivity type on the surface side of the substrate; and a first impurity diffusion region of a first conductivity type between the first buried layer and the second contact region, and the second device isolation region may include: a second buried layer of a first conductivity type within the substrate; a third contact region of a first conductivity type on the surface side of the substrate; and a second impurity diffusion region of a first conductivity type between the second buried layer and the third contact region.

According to still another embodiment of the present disclosure, a power semiconductor device according to the present disclosure may include: a high voltage unit configured to output high voltage; a low voltage unit configured to output low voltage; a capacitor configured to be electrically connected to the high voltage unit and to provide power to the high voltage unit while the high voltage is output; a switching unit configured to be electrically connected to the high voltage unit and the capacitor, to connect the capacitor to a driving power supply to charge the capacitor while the low voltage is output, and to prevent the high voltage unit and the driving power supply from being electrically connected to each other while the high voltage is output; a resistance unit configured to be electrically connected between the switching unit and the high voltage unit and to drop the high voltage to a voltage lower than a breakdown voltage of the switching unit while the high voltage is output; and a guard ring region between the switching unit and the resistance unit, wherein the switching unit may include: a field oxide film on a surface side of a substrate; and positive and negative electrode layers on the field oxide film on the surface side of the substrate.

According to still another embodiment of the present disclosure, in the power semiconductor device, the guard ring region may include: a first contact region of a second conductivity type located on the surface side of the substrate and electrically connected to a ground terminal; and a first well region of a second conductivity type surrounding the first contact region.

According to still another embodiment of the present disclosure, in the power semiconductor device, the guard ring region may further include a buried layer of a second conductivity type below the first well region.

The present disclosure has the following effects by the above configurations.

According to the present disclosure, by forming a guard ring region connected to the ground terminal between a resistance unit and a switching unit, it is possible to allow electrostatic discharge (ESD) current to be discharged to a ground terminal when the current flows in.

Furthermore, according to the present disclosure, by forming a sixth contact region, a second well region and a third well region to enable silicon controlled rectifier (SCR) operation, it is possible to further improve ESD protection performance.

Furthermore, according to the present disclosure, by not utilizing a separate transistor to prevent high voltage from being applied to a switching unit from a high voltage unit, it is possible to reduce the overall size of a power semiconductor device.

Furthermore, according to the present disclosure, by ensuring that a P-TOP region formed in a resistance unit is spaced apart from a field oxide film thereabove, it is possible to prevent a decrease in total current amount due to an increase in the length of a current movement path.

Meanwhile, it should be added that even if effects are not explicitly mentioned herein, the effects described in the following specification expected by the technical features of the present disclosure and their potential effects are treated as if they were described in the specification of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is an equivalent circuit diagram showing a power semiconductor device according to an embodiment of the present disclosure;

FIG. 2 is a plan view of the power semiconductor device shown in FIG. 1;

FIG. 3 is a cross-sectional view taken along line AA′ of a power semiconductor device according to a first embodiment of the present disclosure;

FIG. 4 is a cross-sectional view taken along line AA′ of a power semiconductor device according to a second embodiment of the present disclosure; and

FIG. 5 is a cross-sectional view taken along line AA′ of a power semiconductor device according to a third embodiment of the present disclosure.

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are only provided for reference in order to more completely explain the present disclosure to those of ordinary skill in the art.

As used herein, the singular form may include the plural form unless the context clearly indicates otherwise. In addition, as used herein, “comprise” and/or “comprising” specify the presence of the recited shapes, numbers, steps, operations, members, elements, and/or groups thereof, but do not exclude the presence or addition of one or more other shapes, numbers, steps, operations, members, elements, and/or groups thereof.

Hereinafter, it should be noted that when one component (or layer) is described as being disposed on another component (or layer), one component may be disposed directly on another component, or another component(s) or layer(s) may be located between the components. In addition, when one component is expressed as being directly disposed on or above another component, no other component(s) are located between the components. Moreover, being located on “top”, “upper”, “lower”, “top”, “bottom” or “one (first) side” or “side” of a component means a relative positional relationship.

In addition, the conductivity type or doped region of the components may be defined as “p-type” or “n-type” according to the main carrier characteristics, but this is only for convenience of description, and the technical spirit of the present disclosure is not limited to what is illustrated. For example, hereinafter, “p-type” or “n-type” will be used as more general terms “first conductivity type” or “second conductivity type”, and here, the first conductivity type means p-type, and the second conductivity type means n-type.

Additionally, it should be noted that in the following, when describing the components, although numbers are written in front of the components such as “first”, “second”, etc., this is an arbitrary configuration, and the second configuration does not presuppose the first configuration, but is independent of each other.

Furthermore, it should be understood that “high concentration” and “low concentration” expressing the doping concentration of the impurity region mean the relative doping concentration of one component and another component.

Hereinafter, a power semiconductor device 10 according to an embodiment of the present disclosure will be described in detail with reference to the attached drawings.

The present disclosure relates to a power semiconductor device 10 and, more particularly, to a power semiconductor device 10 that allows electrostatic discharge (ESD) current to be discharged to a V_{SS} terminal when the current flows in by forming a guard ring region connected to the ground terminal between a resistance unit and a switching unit.

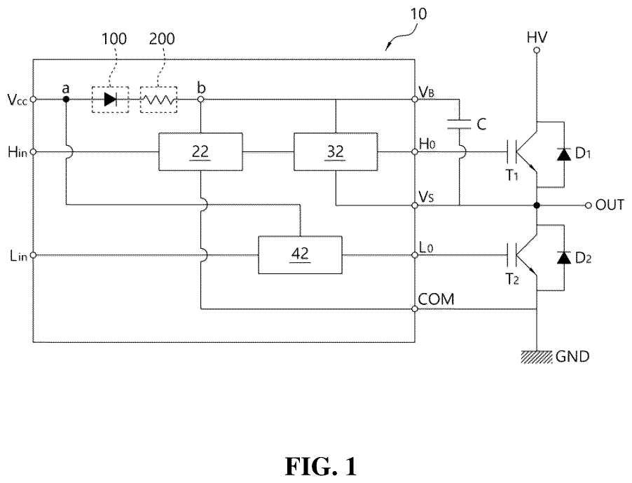

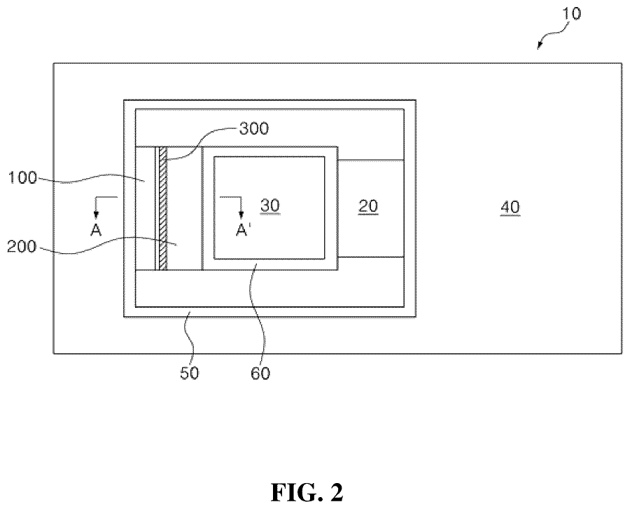

FIG. 1 is an equivalent circuit diagram showing a power semiconductor device according to an embodiment of the present disclosure, and FIG. 2 is a plan view of the power semiconductor device shown in FIG. 1.

Referring to FIGS. 1 and 2, the power semiconductor device 10 according to an embodiment of the present disclosure may include a high voltage unit 30, a low voltage unit 40, a capacitor C, a switching unit 100, and a resistance unit 200. The high voltage unit 30 may include a high voltage driving circuit 32 and a first power transistor T₁, and the low voltage unit 40 may include a low voltage driving circuit 42 and a second power transistor T₂.

In addition, the capacitor C may be connected in parallel to a power line connected to power terminals V_{B} and V_{S} for providing power to the high voltage driving circuit 32. An output terminal H_{O} of the high voltage driving circuit 32 is connected to a gate of the first power transistor T₁, and the first power transistor T₁ may be connected in parallel with a first diode D₁. An output terminal L_{O} of the low voltage driving circuit 42 is connected to a gate of the second power transistor T₂, and the second power transistor T₂ may be connected in parallel with a second diode D₂. A source of the first power transistor T₁ may be connected to high voltage HV, the first power transistor T₁ and the second power transistor T₂ may be connected in series, and a drain of the second power transistor T₂ may be connected to a ground terminal GND.

In addition, the low voltage driving circuit 42 may control the second power transistor T₂ by outputting a low voltage control signal to the low voltage output terminal L_{O} according to a signal input through a low voltage input terminal Lᵢₙ. The low voltage driving circuit 42 may operate by receiving power supplied from a driving power supply V_{CC} and a common terminal COM, for example, a potential difference between ground voltage and driving voltage.

The high voltage driving circuit 32 may control the first power transistor T₁ by outputting a high voltage control signal to the high voltage output terminal H_{O} in response to a signal provided from a level shift circuit 22. The high voltage driving circuit 32 may operate by receiving power supplied from the capacitor C, which is connected between the terminal V_{S} and the terminal V_{B} having the same potential as an output terminal OUT. The level shift circuit 22 may provide a signal input from a high voltage input terminal Hᵢₙ to the high voltage driving circuit 32. A reference voltage of the high voltage driving circuit 32 may be high voltage HV or low voltage, for example, ground voltage, depending on the state of a pulse width modulation (PWM) signal output from the output terminal OUT.

The power semiconductor device 10 may output the high voltage HV or the low voltage, for example, the ground voltage, to the output terminal OUT in response to signals input from the high voltage input terminal Hᵢₙ and the low voltage input terminal Lᵢₙ. To be specific, when the low voltage driving circuit 42 turns on the second power transistor T₂, the output terminal OUT may output the low voltage, for example, the ground voltage. In this case, the second diode D₂ prevents a reverse voltage. In addition, in order to prevent the high and low voltages from being applied together to the output terminal OUT, the high voltage driving circuit 32 may turn off the first power transistor T₁. That is, ground voltage applied to the output terminal OUT and driving voltage from the driving power supply V_{CC} may be applied to the high voltage driving circuit 32.

In addition, the driving power supply V_{CC} may charge the capacitor C to approximately the same level as the driving voltage by providing a current to the capacitor C through the switching unit 100 and the resistance unit 200.

When the low voltage driving circuit 42 outputs an off signal and the high voltage driving circuit 32 provides an on signal to the first power transistor T₁ through the high voltage output terminal H_{O} to turn on the first power transistor T₁, the output terminal OUT may output the high voltage HV. In this case, the first diode D₁ prevents a reverse voltage. In addition, the high voltage HV may be applied to the terminal V_{S} and the high voltage HV and a charging voltage of the capacitor C may be applied to the terminal V_{B}.

According to an embodiment of the present disclosure, the switching unit 100 may include a bipolar junction transistor or diode. In particular, when the high voltage unit 30 outputs high voltage, driving voltage may be applied to a node a, and the high voltage HV and the charging voltage of the capacitor C may be applied to a node b. As a result, a reverse voltage is applied to the switching unit 100, and thus the switching unit 100 may prevent the high voltage unit 30 and the driving power supply V_{CC} from being electrically connected to each other.

However, since a potential difference between the nodes a and b is so high that the potential difference reaches the high voltage HV, the switching unit 100 may be destroyed. To prevent this, the resistance unit 200 may be placed between the switching unit 100 and the high voltage unit 30. The resistance unit 200 may drop the high voltage HV to a voltage lower than a breakdown voltage of the switching unit 100 while the high voltage HV is output. Due to this, the switching unit 100 may be prevented from being destroyed by a reverse voltage.

Referring to FIG. 2, the power semiconductor device 10 may be formed on a substrate, for example, a semiconductor wafer. To be specific, the low voltage unit 40 may be formed to surround the high voltage unit 30, and a first device isolation region 50 and a second device isolation region 60 may be formed between the high voltage unit 30 and the low voltage unit 40. In addition, a level shift region 20 in which the level shift circuit 22 is formed may be provided between the high voltage unit 30 and the low voltage unit 40. The switching unit 100 and the resistance unit 200 may be provided between the high voltage unit 30 and the low voltage unit 40. In this case, the resistance unit 200 may be formed between the switching unit 100 and the high voltage unit 30. In addition, a guard ring region 300 may be formed between the switching unit 100 and the resistance unit 200.

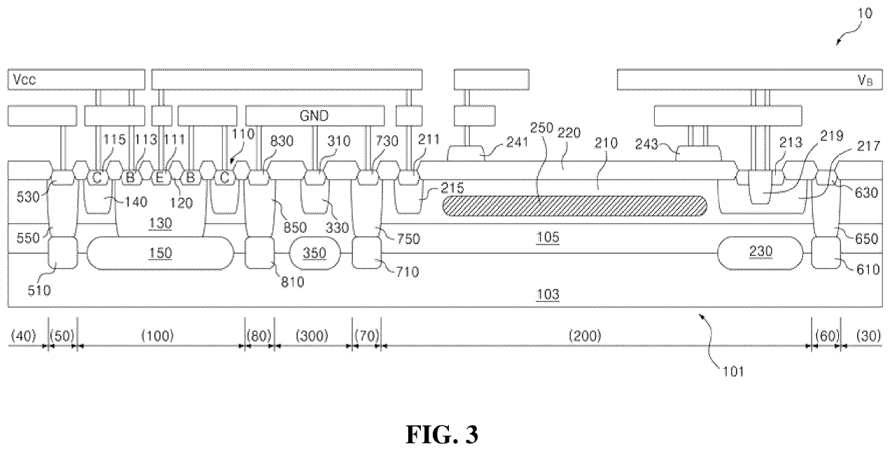

FIG. 3 is a cross-sectional view taken along line AA′ of a power semiconductor device according to a first embodiment of the present disclosure.

Referring to FIG. 3, the switching unit 100 according to an embodiment of the present disclosure may include an NPN bipolar junction transistor 110. The NPN bipolar junction transistor 110 may include, for example, an emitter region 111, a base region 113, and a collector region 115 on or on the surface of a substrate 101. In this case, the substrate 101 may include a silicon substrate 103 of a first conductivity type and an epitaxial layer 105 of a second conductivity type grown on the silicon substrate 103. In addition, the emitter region 111 may be a doped region with a high concentration of impurities of the second conductivity type, the base region 113 may be a doped region with a high concentration of impurities of the first conductivity type, and the collector region 115 may be a doped region with a high concentration of impurities of the second conductivity type.

For example, the base region 113 may be formed in a ring shape to surround the emitter region 111, and the collector region 115 may also be formed in a ring shape to surround the base region 113. A field oxide film 120 may be individually formed between the emitter region 111, the base region 113, and the collector region 115. The emitter region 111, the base region 113, and the collector region 115 may be spaced apart from each other by the field oxide film 120. The field oxide layer 120 may be an STI region, for example, but there is no separate limitation thereon.

The base region 113 and the collector region 115 may be electrically connected to the driving power supply V_{CC} by metal wiring and a contact plug, and the emitter region 111 may be electrically connected to the resistance unit 200 by metal wiring and a contact plug. Due to this structure, when low voltage is output from the low voltage unit 40, current flows from the base region 113 and the collector region 115 to the emitter region 111, and the current may charge the capacitor C through the resistance unit 200.

In addition, a deep well region 130 of a first conductivity type formed at a predetermined depth within the substrate 101 may be formed in the switching unit 100. The deep well region 130 of the first conductivity type is preferably a doped region with a lower concentration of impurities compared to the base region 113. The deep well region 130 may be formed to surround the emitter region 111 and the base region 113.

The switching unit 100 may also have a well region 140 of a second conductivity type formed at a predetermined depth within the substrate 101. The well region 140 of the second conductivity type is configured to surround the collector region 115, and the internal resistance of the bipolar junction transistor 110 may be reduced by the well region 140 of the second conductivity type.

A buried layer 150 of a second conductivity type may be formed under the deep well region 130 in the substrate 101. The buried layer 150 is configured to reduce leakage current of the bipolar junction transistor 110.

In addition, the first device isolation region 50 may be formed between the low voltage unit 40 and the switching unit 100. The first device isolation region 50 may include a first buried layer 510 in the substrate 101, a first contact region 530 on the surface side of the substrate 101, and a first impurity diffusion region 550 between the first buried layer 510 and the first contact region 530. In this case, the first buried layer 510, the first contact region 530, and the first impurity diffusion region 550 are impurity doped regions of the first conductivity type, and the first contact region 530 may be an impurity doped region with a higher concentration than the first buried layer 510 and the first impurity diffusion region 550.

In addition, the second device isolation region 60 may be formed between the high voltage unit 30 and the resistance unit 200. The second device isolation region 60 may include a second buried layer 610 in the substrate 101, a second contact region 630 on the surface side of the substrate 101, and a second impurity diffusion region 650 between the second buried layer 610 and the second contact region 630. In this case, the second buried layer 610, the second contact region 630, and the second impurity diffusion region 650 are impurity doped regions of the first conductivity type, and the second contact region 630 may be an impurity doped region with a higher concentration than the second buried layer 610 and the second impurity diffusion region 650.

Although not shown in FIG. 2, a third device isolation region 70 may be formed between the switching unit 100 and the resistance unit 200. The third device isolation region 70 may include a third buried layer 710 in the substrate 101, a third contact region 730 on the surface side of the substrate 101, and a third impurity diffusion region 750 between the third buried layer 710 and the third contact region 730. In this case, the third buried layer 710, the third contact region 730, and the third impurity diffusion region 750 are impurity doped regions of the first conductivity type, and the third contact region 730 may be an impurity doped region with a higher concentration than the third buried layer 710 and the third impurity diffusion region 750. In addition, the third device isolation region 70 including the third contact region 730 may be electrically connected to the ground terminal GND by a metal wire and a contact plug.

In addition, although not shown in FIG. 2, a fourth device isolation region 80 may be formed between the third device isolation region 70 and the switching unit 100. The fourth device isolation region 80 may include a fourth buried layer 810 in the substrate 101, a fourth contact region 830 on the surface side of the substrate 101, and a fourth impurity diffusion region 850 between the fourth buried layer 810 and the fourth contact region 830. In this case, the fourth buried layer 810, the fourth contact region 830, and the fourth impurity diffusion region 850 impurity doped regions of the first conductivity type, and the fourth contact region 830 may be an impurity doped region with a higher concentration than the fourth buried layer 810 and the fourth impurity diffusion region 850. In addition, the fourth device isolation region 80 including the fourth contact region 830 may be electrically connected to the ground terminal GND by a metal wire and a contact plug.

The resistance unit 200 may be formed between the second device isolation region 60 and the third device isolation region 70. The resistance unit 200 may include a deep well region 210 of a second conductivity type formed in the substrate 101. The deep well region 210 of the second conductivity type may be formed, for example, on an epitaxial layer 105. When the low voltage unit 40 outputs a low voltage, a forward voltage is applied to the bipolar junction transistor 110 and the resistance unit 200, so that the electrical resistance of the deep well region 210 of the second conductivity type may be reduced. When the high voltage unit 30 outputs a high voltage, a reverse voltage is applied to the bipolar junction transistor 110 and the resistance unit 200, so that the electrical resistance of the deep well region 210 may increase.

In addition, the resistance unit 200 may include a field oxide film 220 formed on the surface (or upper surface) side of the substrate 101. The field oxide film 220 may be, for example, a LOCOS or STI region, and may be formed on the deep well region 210 of the second conductivity type.

The resistance unit 200 may include a fifth contact region 211 and a sixth contact region 213 formed on the surface side of the substrate 101. The fifth contact region 211 and the sixth contact region 213 are spaced apart from each other, and may be formed to be surrounded by the deep well region 210 of the second conductivity type. The fifth contact region 211 and the sixth contact region 213 are doped regions with high concentration of impurities of the second conductivity type. The fifth contact region 211 may be formed on a side adjacent to the switching unit 100, and the sixth contact region 213 may be formed on a side adjacent to the high voltage unit 30. The fifth contact region 211 may be electrically connected to the switching unit 100, and the sixth contact region 213 may be electrically connected to the high voltage unit 30.

In addition, within the deep well region 210, a first well region 215 may be formed to surround the fifth contact region 211, and a second well region 217 may be formed to surround the sixth contact region 213. The first well region 215 and the second well region 217 are both impurity doped regions of the second conductivity type and may be doped regions with a lower concentration of impurities compared to the fifth contact region 211 and the sixth contact region 213. The deep well region 210 is a doped region with a lower impurity concentration compared to the first well region 215 and the second well region 217, and may be formed to surround the first well region 215 and the second well region 217.

In addition, the fifth contact region 211 may be electrically connected to the switching unit 100 by metal wiring and a contact plug, and the sixth contact region 213 may be electrically connected to the high voltage unit 30 and the capacitor C through metal wiring and a contact plug.

The impurity concentration of the deep well region 210 may be appropriately adjusted to lower the high voltage to a voltage lower than the breakdown voltage of the switching unit 100 while the high voltage is output. To be specific, the deep well region 210 may drop the high voltage to a voltage lower than the breakdown voltage of the switching unit 100 and higher than the driving voltage. As a result, even if a reverse voltage is applied to the switching unit 100 while the high voltage is applied, destruction of the switching unit 100 may be prevented because the reverse voltage is lower than the breakdown voltage of the switching unit 100.

Next, a third well region 219 is formed on the surface side of the substrate within the sixth contact region 213 and the second well region 217, enabling silicon controlled rectifier (SCR) operation to improve ESD protection performance. The third well region 219 is an impurity doped region of the first conductivity type. It should be noted that the described third well region 219 is not an essential component of the present disclosure.

In addition, in the substrate 101, a buried layer 230 of a second conductivity type may be formed to disperse the electric field caused by high voltage when the high voltage is applied to the sixth contact region 213 from the high voltage unit 30. As an example, the buried layer 230 of the second conductivity type may be formed below the second well region 217.

On the field oxide film 220 formed in the resistance unit 200, a first electrode layer 241 may be formed adjacent to the switching unit 100, and a second electrode layer 243 may be formed adjacent to the high voltage unit 30. The first electrode layer 241 may be electrically connected to the ground terminal GND, and the second electrode layer 243 may be electrically connected to the high voltage unit 30. The first electrode layer 241 and the second electrode layer 243 may include, for example, polysilicon doped with a second conductivity type impurity.

In addition, the resistance unit 200 may include a P-TOP region 250 in the deep well region 210 of the second conductivity type. The P-TOP region 250 is an impurity doped region of the first conductivity type, and may be formed in contact with the field oxide film 220 or spaced apart from the field oxide film 220. That is, the P-TOP region 250 may be formed below the field oxide film 220 and spaced apart from the bottom of the field oxide film 220. For example, when the P-TOP region 250 is spaced apart from the field oxide film 220, a depletion layer may be formed between the top surface of the P-TOP region 250 and the deep well region 210 and between the bottom surface of the P-TOP region 250 and the deep well region 210. To be specific, while the high voltage unit 30 outputs a high voltage, the depletion layer may be expanded by the high voltage applied to the sixth contact region 213, and accordingly, the electrical resistance of the resistance unit 200 may increase. In addition, the depletion layer may be formed more uniformly due to the first electrode layer 241 and the second electrode layer 243. By forming the P-TOP region 250 in this way, a triple reduced surface field (RESURF) structure of the upper and lower surface sides of the P-TOP region 250 and the interface between the silicon substrate 101 and an epitaxial layer 103 may be achieved.

As previously described, as an example, the P-TOP region 250 may be formed below the field oxide film 220 and spaced apart from the bottom of the field oxide film 220. In contrast, when the P-TOP region 250 is formed in contact with the bottom surface of the field oxide film 220, the current flowing from the sixth contact region 213 to the fifth contact region 211 flows in a detour along the lower side of the P-TOP region 250, and the length of the current path becomes longer, and thus the total amount of current is reduced.

The guard ring region 300 may be formed between the third device isolation region 70 and the fourth isolation region 80. The guard ring region 300 is a configuration for discharging the incoming current to the ground terminal GND when ESD current flows in. To this end, the guard ring region 300 may include an eighth contact region 310 on the substrate surface side and a fourth well region 330 surrounding the eighth contact region 310. The eighth contact region 310 and the fourth well region 330 are both impurity doped regions of the second conductivity type, and it is preferable that the eighth contact region 310 is a doped region with a higher concentration of impurities than the fourth well region 330. A buried layer 350 of a second conductivity type may be formed below the fourth well region 330. It is preferable that the buried layer 350 is spaced apart from the fourth well region 330.

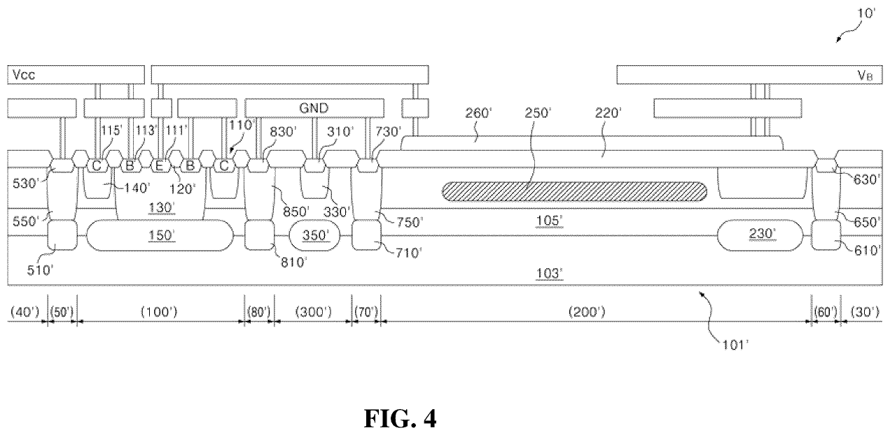

FIG. 4 is a cross-sectional view taken along line AA′ of a power semiconductor device according to a second embodiment of the present disclosure.

Referring to FIG. 4, in the second embodiment, a resistance unit 200′ may include a single electrode layer 260′ on a field oxide film 220′instead of the above-described first electrode layer 241 and second electrode layer 243. The electrode layer 260′ extends long on the field oxide film 220′, and may be configured such that the side of the electrode layer 260′ adjacent to a switching unit 100′ is electrically connected to the switching unit 100′ while the side of the electrode layer 260′ adjacent to a high voltage unit 30′ is electrically connected to the high voltage unit 30′ and the capacitor C. The electrode layer 260′ may be a polysilicon film doped with impurities of the second conductivity type, and the impurity concentration of the electrode layer 260′ may be controlled to drop high voltage to a voltage lower than a breakdown voltage of the switching unit 100′ while the high voltage is output.

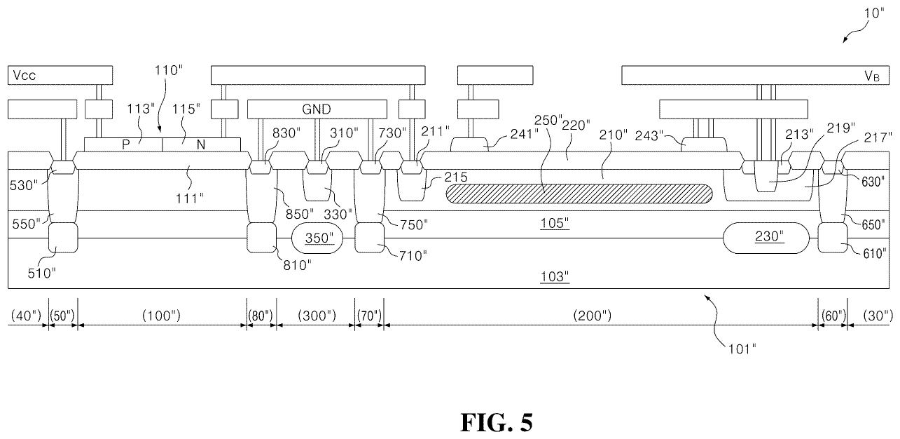

FIG. 5 is a cross-sectional view taken along line AA′ of a power semiconductor device according to a third embodiment of the present disclosure.

Referring to FIG. 5, in this embodiment, a switching unit 100″ may include a diode 110″ on a substrate 101″. The diode 110″ may be configured to include: a field oxide film 111″ including, for example, an oxide film, on the surface side of the substrate 101″; and a positive electrode layer 113″ and a negative electrode layer 115″ on the field oxide film 111″. In this case the positive electrode layer 113″ and the negative electrode layer 115″ may be in contact with each other. The positive electrode layer 113″ may be a polysilicon film doped with impurities of a first conductivity type, and the negative electrode layer 115″ may be a polysilicon film doped with impurities of a second conductivity type.

In addition, the positive electrode layer 113″ may electrically connected to the driving power supply V_{CC}, and the negative electrode layer 115″ may electrically connected to a fourth contact region 211″ of the resistance unit 200″.

The above detailed description is illustrative of the present disclosure. In addition, the above description shows and describes preferred embodiments of the present disclosure, and the present disclosure can be used in various other combinations, modifications, and environments. In other words, changes or modifications are possible within the scope of the concept of the disclosure disclosed herein, the scope equivalent to the written disclosure, and/or within the scope of skill or knowledge in the art. The above-described embodiment describes the best state for implementing the technical idea of the present disclosure, and various changes required in the specific application field and use of the present disclosure are possible. Accordingly, the detailed description of the present disclosure is not intended to limit the present disclosure to the disclosed embodiments.

What is claimed is:

1. A power semiconductor device, comprising:
a high voltage unit configured to output a first voltage;
a low voltage unit configured to output a second voltage, wherein the first voltage is higher than the second voltage;
a capacitor configured to be electrically connected to the high voltage unit and to provide power to the high voltage unit while the first voltage is being output;
a switching unit configured to be electrically connected to the high voltage unit and the capacitor, to connect the capacitor to a driving power supply to charge the capacitor while the second voltage is being output, and to prevent the high voltage unit and the driving power supply from being electrically connected to each other while the first voltage is being output;
a resistance unit configured to be electrically connected between the switching unit and the high voltage unit and to drop the first voltage to a voltage lower than a breakdown voltage of the switching unit while the first voltage is being output; and
a guard ring region disposed between the switching unit and the resistance unit.

2. The power semiconductor device of claim 1,
wherein the guard ring region comprises:
a first contact region of a second conductivity type disposed on a surface side of a substrate; and
a first well region of the second conductivity type surrounding the first contact region.

3. The power semiconductor device of claim 2, wherein the first contact region is electrically connected to a ground terminal.

4. The power semiconductor device of claim 2,
wherein the guard ring region further comprises:
a buried layer of a second conductivity type disposed below the first well region.

5. The power semiconductor device of claim 3, further comprising:
a first device isolation region disposed between the switching unit and the resistance unit,
wherein the first device isolation region comprises:
a first buried layer of a first conductivity type disposed within the substrate;
a second contact region of the first conductivity type disposed on the surface side of the substrate; and
a first impurity diffusion region of the first conductivity type disposed between the first buried layer and the second contact region.

6. The power semiconductor device of claim 5, further comprising:
a second device isolation region disposed between the first device isolation region and the switching unit,
wherein the second device isolation region comprises:
a second buried layer of the first conductivity type disposed within the substrate;
a third contact region of the first conductivity type disposed on the surface side of the substrate; and
a second impurity diffusion region of the first conductivity type disposed between the second buried layer and the third contact region.

7. The power semiconductor device of claim 6, wherein the guard ring region is disposed between the first device isolation region and the second device isolation region.

8. The power semiconductor device of claim 1,
wherein the resistance unit comprises:
a deep well region of a second conductivity type extending from a substrate surface to a predetermined depth;
a fourth contact region of the second conductivity type disposed on a side of the substrate surface adjacent to the switching unit; and
a fifth contact region of the second conductivity type disposed on another side of the substrate surface adjacent to the high voltage unit,
wherein the fourth contact region and the fifth contact region are surrounded by the deep well region.

9. The power semiconductor device of claim 8, wherein the fourth contact region is electrically connected to the switching unit, and the fifth contact region is electrically connected to the high voltage unit.

10. The power semiconductor device of claim 8,
wherein the resistance unit further comprises:
a second well region of the second conductivity type disposed below the fourth or fifth contact region.

11. The power semiconductor device of claim 10,
wherein the resistance unit further comprises:
a third well region of a first conductivity type disposed within the fifth contact region and the second well region disposed below the fifth contact region.

12. A power semiconductor device, comprising:
a high voltage unit configured to output a first voltage;
a low voltage unit configured to output a second voltage, wherein the first voltage is higher than the second voltage;
a capacitor configured to be electrically connected to the high voltage unit and to provide power to the high voltage unit while the first voltage is being output;
a bipolar junction transistor configured to be electrically connected to the high voltage unit and the capacitor, to connect the capacitor to a driving power supply to charge the capacitor while the second voltage is being output, and to prevent the high voltage unit and the driving power supply from being electrically connected to each other while the first voltage is being output;
a resistance unit configured to be electrically connected between the bipolar junction transistor and the high voltage unit and to drop the first voltage to a voltage lower than a breakdown voltage of the bipolar junction transistor while the first voltage is being output; and
a guard ring region disposed between the bipolar junction transistor and the resistance unit,
wherein the guard ring region comprises:
a first contact region of a second conductivity type disposed on a surface side of a substrate and electrically connected to a ground terminal; and
a first well region of the second conductivity type surrounding the first contact region.

13. The power semiconductor device of claim 12,
wherein the bipolar junction transistor comprises:
an emitter region of a second conductivity type disposed on the substrate;
a base region of a first conductivity type disposed on the substrate; and
a collector region of the second conductivity type disposed on the substrate,
wherein the base region and the collector region are electrically connected to the driving power supply, and
wherein the emitter region is electrically connected to the resistance unit.

14. The power semiconductor device of claim 12,
wherein the resistance unit comprises:
a deep well region of a second conductivity type disposed within the substrate;
a field oxide film disposed on the surface side of the substrate; and
a P-TOP region spaced apart from the field oxide film, the P-TOP region being disposed within the deep well region.

15. The power semiconductor device of claim 14,
wherein the resistance unit further comprises:
a single electrode layer disposed on the field oxide film.

16. The power semiconductor device of claim 12, further comprising:
a first device isolation region disposed between the bipolar junction transistor and the resistance unit; and
a second device isolation region disposed between the first device isolation region and the bipolar junction transistor,
wherein the first device isolation region comprises:
a first buried layer of a first conductivity type disposed within the substrate;
a second contact region of the first conductivity type disposed on the surface side of the substrate; and
a first impurity diffusion region of the first conductivity type disposed between the first buried layer and the second contact region, and
wherein the second device isolation region comprises:
a second buried layer of the first conductivity type disposed within the substrate;
a third contact region of the first conductivity type disposed on the surface side of the substrate; and
a second impurity diffusion region of the first conductivity type disposed between the second buried layer and the third contact region.

17. A power semiconductor device, comprising:
a high voltage unit configured to output a first voltage;
a low voltage unit configured to output a second voltage, wherein the first voltage is higher than the second voltage;
a capacitor configured to be electrically connected to the high voltage unit and to provide power to the high voltage unit while the first voltage is being output;
a switching unit configured to be electrically connected to the high voltage unit and the capacitor, to connect the capacitor to a driving power supply to charge the capacitor while the second voltage is being output, and to prevent the high voltage unit and the driving power supply from being electrically connected to each other while the first voltage is being output;
a resistance unit configured to be electrically connected between the switching unit and the high voltage unit and to drop the first voltage to a voltage lower than a breakdown voltage of the switching unit while the first voltage is being output; and
a guard ring region disposed between the switching unit and the resistance unit,
wherein the switching unit comprises:
a field oxide film disposed on a surface side of a substrate; and
positive and negative electrode layers disposed on the field oxide film.

18. The power semiconductor device of claim 17,
wherein the guard ring region comprises:
a first contact region of a second conductivity type disposed on the surface side of the substrate and electrically connected to a ground terminal; and
a first well region of the second conductivity type surrounding the first contact region.

19. The power semiconductor device of claim 18,
wherein the guard ring region further comprises:
a buried layer of the second conductivity type disposed below the first well region.
